(19) United States
(12) Patent Application Publication
(10) Pub. No.: US 2006/0121717 A1
(43) Pub. Date: Jun. 8, 2006

(54) Bonding structure and fabrication thereof

(75) Inventors: Chen-Hua Yu, Keelung City (TW); Chung-Shi Liu, Hsinchu City (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD., Hsin-Chu (TW)

(21) Appl. No.: 11/001,003

(22) Filed: Dec. 2, 2004

(51) Int. Cl. H01L 21/44

(52) U.S. Cl. 438/612; 438/614

(57) ABSTRACT

Bonding structure and method of fabricating the same. The bonding structure of the invention includes an insulating layer having at least one metal segment formed thereon and a bonding pad over the metal segment, wherein the bonding pad is substantially surrounded by a first passivation layer comprising a first atomic hydrogen penetrable layer.

### BACKGROUND

The present invention relates to a semiconductor structure and in particular to a bonding structure adopting atomic hydrogen penetrable passivation.

Conventional semiconductor devices typically comprise a semiconductor substrate, normally of doped monocrystalline silicon, and a plurality of sequentially formed inter-layer dielectrics and interconnected metallization layers defining conductive patterns. An integrated circuit is formed comprising a plurality of conductive patterns including conductive lines separated by interwiring spacings, and a plurality of interconnect lines, such as bus lines, bit lines, word lines and logic interconnect lines. Typically, the conductive patterns on different metallization layers are electrically connected by a conductive plug filling a via opening, while a conductive plug filling a contact opening establishes electrical contact with an active region on a semiconductor substrate, such as a source/drain region. Conductive lines are formed in trenches which typically extend substantially horizontally with respect to the semiconductor substrate. Semiconductor chips comprising s five or more levels of metallization are becoming more prevalent as device geometries are reduced to submicron levels.

In general, the entire surface of a semiconductor device is covered with a final passivation film such as a plasma SiN film after a metal wiring layer electrode layer is formed. A hole is formed in the final passivation layer to partly expose the electrode layer so that the exposed portion thereof can be used as a bonding pad section. An external package pin is connected to the bonding pad section by a bonding technique such as wire bonding.

Normally, plasma etching is used to form the hole exposing the bonding pad section therein. Charges formed in the plasma etching are thus conducted to the underlying active regions by the bonding pad section and the underlying interconnects thereof during the described hole formation. Undesired plasma charging thus occurs in the active region such as the source/drain regions of an underlying transistor device, causing damage induced by the plasma charging such as hot carrier integration (HCI) and threshold voltage (Vₜₕ) shifting to an underlying semiconductor device.

In U.S. Pat. No. 6,358,631, Liu et. al. disclose a bonding pad placed above the plane of the wiring channels of the interconnection level to eliminate dishing of the relatively large bonding pads. In U.S. Pat. No. 6,358,631, the disclosed bonding pad on a bonding base segment provides a more robust pad and covers a portion of etching stop layer constituting silicon nitride or silicon oxynitride and passivated by a layer of silicon nitride or a composite layer of phosphosilicate glass (PSG) over silicon oxide.

Neverless, the passivation layer disclosed in U.S. Pat. No. 6,358,631 is suggested to be patterned by plasma etching to expose the bonding pad, whereby the undesired plasma charging can stilled occur on the semiconductor device formed on a substrate.

Hence, there is a need for a better passivation to a bonding structure to provide passivation against plasma induced charging by the plasma used during formation of the final passivation layer.

### SUMMARY

Accordingly, an object of the invention is to provide a bonding structure with reduced plasma induced damages.

Thus, the bonding structure in accordance with one embodiment of the invention includes an insulating layer having at least one metal segment formed thereon and a bonding pad over the metal segment, wherein the bonding pad is substantially surrounded by a first passivation layer comprising a first atomic hydrogen penetrable layer.

Further, a second passivation layer can be disposed over the first passiviation layer to partially cover a portion of the bonding pad to provide a bonding structure in accordance with another embodiment of the invention, having improved dual passivation structure. Optionally, a second atomic hydrogen penetrable layer can be disposed between the second passivation layer and the first passivation layer to allow self-repair to underlying semiconductor devices by the hydrogen atoms formed during formation of the second passivation layer.

Another object of the invention is to provide a method of fabricating a bonding structure, comprising providing a substrate and forming an insulating layer having at least one metal segment formed thereon. A first passivation layer is then formed on the insulating layer and the metal segment, wherein the first passivation layer comprises a first atomic hydrogen penetrable layer. An opening is then formed in the first passivation layer to expose a portion of the metal segment and a metal layer is then formed in the opening to cover the metal segment and a portion of the adjacent passivation layer thereof as a bonding pad.

In one embodiment of the invention, thermal annealing using hydrogen-containing reacting gases is performed on the first passivation layer prior to the formation of the metal layer.

Further, in another embodiment of the invention, a second passivation layer can be further formed over the first passivation layer and the bonding pad in a position relative to the bonding pad, which is then patterned to partially expose the bonding pad. Optionally, a second atomic hydrogen penetrable layer can be formed over the first passivaiton layer adjacent to the bonding pad prior to formation of the second passivation layer to allow self-repair to the underlying semiconductor devices of the insulating layer by the hydrogen atoms formed during formation of the second passivation layer.

In the present invention, the atomic hydrogen penetrable layer adopts dielectric such as silicon carbide, more easily penetrated by the hydrogen atoms than conventional silicon nitride. Thus, hydrogen atoms formed either in formation of the first or the second passivation layer or during etching of the passivation layers can penetrate the atomic hydrogen penetrable layer, and undesired damages induced by plasma charging such as hot carrier integrity or threshold voltage shifting happened adjacent to the underlying semiconductor device can be reduced or eliminated by neutralization (or compensation) of the hydrogen atoms penetrating through the dielectric layers, whereby reliability thereof is ensured.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1 to 6 are schematic cross sections of the process for fabricating a bonding structure of the invention.

### DESCRIPTION

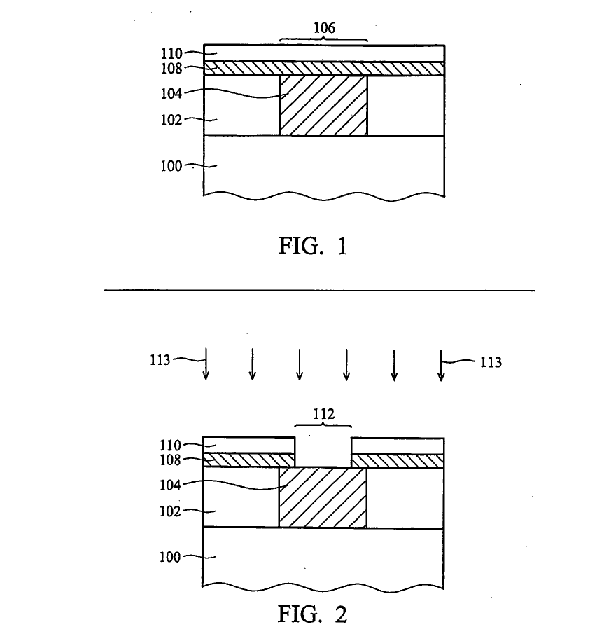

FIGS. 1 to 6 are schematic cross sections during the process for fabricating a bonding structure of the invention.

In FIG. 1, an integrated circuit (IC) structure 100 with a metal segment 104 formed thereon is provided. The IC structure 100 may comprise a semiconductor substrate (not shown) having integrated circuit devices and multilayer interconnection structures formed thereon. The integrated circuit devices can be active or passive devices formed on the semiconductor substrate, and the multilayer interconnection structures can be multiple metallization layers supported and spaced by inter-layer dielectric. The integrated circuit devices and multilayer interconnection structures formed, however, are not shown in the integrated circuit structure 100 for simplicity.

The integrated circuit (IC) structure 100 having a metal segment 104 is fabricated by the following steps. First, an insulating layer 102 is formed on the IC structure 100. Material of the insulating layer 102 can be oxide, polymers, spin-on glass (SOG), low-k dielectric, or a combination thereof that other than nitride. The low-k dielectric can be either organic dielectric such as benzocyclobutene (BCB), SiLK, available from Dow Chemical, and Flare, available from Allied Signal of Morristown or inorganic dielectric such as hydrogen silsesquioxane (HSQ), fluorocarbon silsesquioxane (FSQ), methylsilsesquioxane (MSQ), nanoglass, or the like. The insulating layer 102 is preferably formed using chemical vapor deposition (CVD) or spin-on coating, although other deposition techniques can be employed as well.

Next, an opening 106 is formed in the insulating layer 102 through, for example, conventional damascene technique, wherein the opening 106 can function as, for example, a via opening forming interconnect or a device opening forming conductive line. A metal segment 104 is then formed in the opening 106. The metal segment 104 can be formed by blanket deposition of metal material over the insulating layer 102 and in the opening 106. The metal material can be tungsten, aluminum, copper or an alloy thereof. The portion of metal over the insulating layer 102 is then planarized by etching or chemical mechanical polishing (CMP). The metal segment 104 is thus left in the opening 106 and the top surface thereof is exposed. The metal segment 104 can be, for example, copper, tungsten, aluminum or an alloy thereof.

Next, a first passivation film, comprising an atomic hydrogen penetrable layer 108 and a first dielectric layer 110 formed over the insulating layer 102, covering the metal segment 104 therein. The atomic hydrogen penetrable layer 108 and the first dielectric layer 110 are sequentially formed over the insulating layer 102, with thicknesses thereof are about 300 Å to 1500 Å and 1000 Å to 7000 Å, respectively. Here, as a key feature of the invention, the atomic hydrogen penetrable layer 108 is formed of atomic hydrogen penetrable material with looser atomic structure than nitride such as silicon carbide (SiC) or doped silicon carbide that lightly doped with oxygen atoms, nitrogen atoms, hydrogen atoms or combinations thereof, thus allowing penetration of atomic hydrogen. The first dielectric layer 110 is preferably silicon oxide (SiO) or silicon oxynitride (SiON). The atomic hydrogen penetrable layer 108 and the first dielectric layer 110 can be formed by, for example, chemical vapor deposition (CVD).

In FIG. 2, the first dielectric layer 110 and the atomic hydrogen penetrable layer 108 are then patterned to form a second opening 112 in a position relative to the metal segment 104 and thus expose a portion of the metal segment 104 therein.

Method for patterning the first dielectric layer 110 and the atomic hydrogen penetrable layer 108 is preferably dry etching, such as a plasma etching. However, charges in the plasma can be conducted by a conductive path (not shown) formed by the metal segment 104 and the underlying interconnect (not shown) during plasma etching, thus accumulating charges near the active region of underlying semiconductor devices (not shown) and reliability thereof is affected by the plasma induced charging. Hence, a thermal annealing 113 is needed and then performed in a gas atmosphere containing hydrogen to neutralize (or recover) existing plasma induced charging near the underlying semiconductor device. The thermal annealing 113 can be performed by a furnace or rapid thermal anneal (RTA) apparatus in an atmosphere of formed gas comprising about 10% H₂ and 90% N₂. Process time and process temperature of the thermal annealing 113 are preferably between 5 to 120 min. and 300° C. to 450° C., depending on the annealing apparatus used and can be understood by those skilled in the art. Hydrogen atoms formed in the thermal annealing 113 can penetrate the atomic hydrogen penetrable layer 108 and the underlying dielectric structure formed by the insulating layer 102 and other underlying dielectric layer (not shown). Hydrogen atoms can thus reach the active region to recover damage induced by the plasma etching, and ensuring reliable performance of the underlying semiconductor.

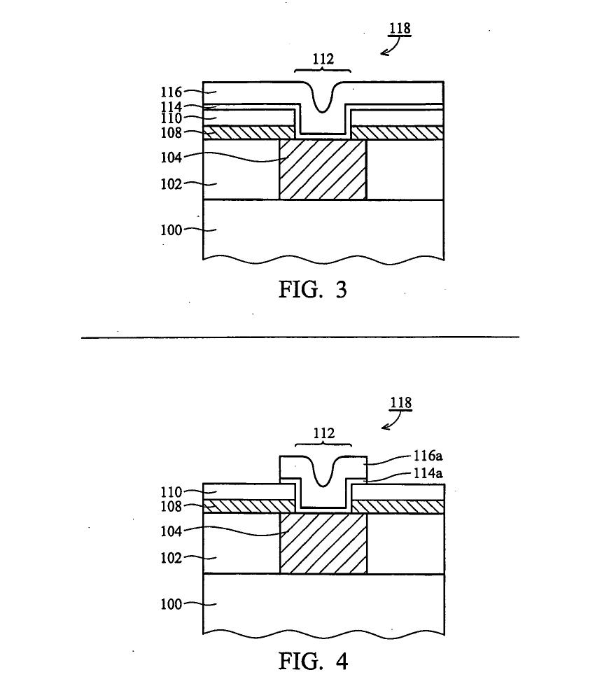

In FIG. 3, a diffusion barrier 114 and a metal layer 116 are then sequentially and conformably formed in the second opening 112 and over the first dielectric layer 110. Here, the diffusion barrier 114 can be, for example, a TaN barrier and the metal layer 116 can be aluminum or aluminum alloy such as an aluminum containing copper (AlCu) layer. Thicknesses of the diffusion barrier layer 114 and the metal layer 116 are about 200 Å to 1000 Å and 4000 Å to 20000 Å, respectively. The diffusion barrier 114 and the metal layer 116 can be formed by, for example, PVD.

In FIG. 4, the metal layer 116 and the diffusion barrier 114 are then patterned to form a bonding pad 118, comprising the patterned metal layer 116a and the patterned diffusion barrier 114a, covering the second opening 112 and a portion of adjacent first dielectric layer 110, thus forming a bonding structure of one embodiment of the invention comprising a bonding pad 118 disposed over a metal segment 104, as shown in FIG. 4. Here, the bonding pad 118 is partially passivated by the first passivation layer including the atomic hydrogen penetrable layer 108 and the first dielectric layer 110 in the bottom portion and exposes a upper portion thereof not passivated by the first passivation layer.

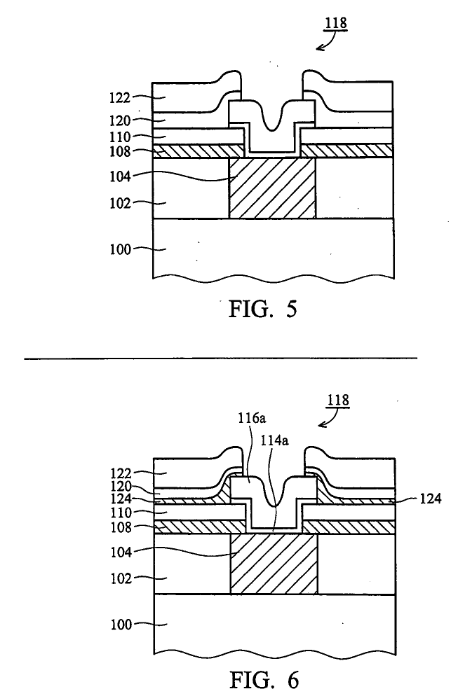

In FIG. 5, a second passivation layer including a second dielectric layer 120 and a third dielectric layer 122 are then formed over the first dielectric layer 110 and the bonding pad 118. Next, these dielectric layers are patterned to expose a portion of bonding pad 118 thereunder. Typically but not necessarily, the second dielectric layer 120 and the third dielectric layer 122 are formed of different materials. The second dielectric layer 120 can be, for example, a layer of silicon oxide or silicon oxynitride and the third dielectric layer 122, for example, a layer of silicon nitride to provide topmost passivation. Thicknesses of the second dielectric layer 120 and the third dielectric layer 122 are about 1000 Å to 7000 Å and 2000 Å to 1000 Å, respectively. The second dielectric layer 120 and the third dielectric layer 122 can be formed by, for example, plasma enhanced chemical vapor deposition (PECVD). Here, as another key feature of the invention, a second atomic hydrogen penetrable layer 124 including atomic hydrogen penetrable material such as silicon carbide (SiC) or doped silicon carbide that lightly doped with oxygen atoms, nitrogen atoms, hydrogen atoms or combinations thereof can be optionally formed over the first dielectric layer 110 prior to formation of the second dielectric layer 120 while the first dielectric layer 110 and the second dielectric layer 120 adopt the same materials or the second dielectric layer adopts nitride such silicon nitride, as shown in FIG. 6. Etching selectivity during patterning of the third dielectric layer 122 and the second dielectric layer 120 is thus improved through use of the second atomic hydrogen penetrable layer 124 while the first dielectric layer 110 and the second dielectric layer 120 adopt the same dielectric material. In addition, self-repair is also provided to the underlying semiconductor devices by the hydrogen atoms formed in the second dielectric layer 120 and the third dielectric layer 122, and also in the etching thereof.

As shown in FIG. 5, another bonding structure comprising a bonding pad 118 disposed over a metal segment 104 of the invention is illustrated. The bonding pad 118 is passivated by dual passivation including a bottom passivation provided by the atomic hydrogen penetrable layer 108 and the first dielectric layer 110 and topmost passivation provided by the second dielectric layer 120 and the third dielectric layer 122. The dual passivation in the invention is sufficiently thick and has a height difference to the top surface of the bonding pad 118 and the topmost passivation thus ensuring mechanical passivation to the bonding pad 118.

Moreover, the second atomic hydrogen penetrable layer 124 can be optionally adopted when the first dielectric layer 110 and the second dielectric layer 120 are the same dielectric or when the second dielectric layer adopts nitride such as silicon nitride, and the material of the second atomic hydrogen penetrable layer 124 is preferably silicon carbide. Thickness of the second atomic hydrogen penetrable layer 124 is about 300 Å to 6000 Å.

Compared with U.S. Pat. No. 6,358,631, the atomic hydrogen penetrable material, such as silicon carbide (SiC) and doped silicon carbide that lightly doped with oxygen atoms, nitrogen atoms and hydrogen atoms, adopted in the atomic hydrogen penetrable layer (referring to the first atomic hydrogen penetrable layer 108 and the optional second atomic hydrogen penetrable layer 124) in the bonding structure shown in FIGS. 4-6 of the invention is more easily penetrated by the hydrogen atoms formed by decomposition of the hydrogen-containing reacting gases such as silane (SiH₄), dichlorosilane (SiH₂Cl₂), TEOS (Si(OC₂H₅)₄) used in the CVD process, hydrogen-containing etchants used in the plasma dry etching, and the hydrogen containing reacting gas in a thermal annealing rather than the conventional silicon nitride layer in the final passivation disclosed in the U.S. Pat. No. 6,358,631

As the bonding structure illustrated in FIGS. 4-6 of the invention, each bonding structure includes at least one atomic hydrogen penetrable layer and the described plasma induced damages can be reduced or eliminated by penetrating hydrogen atoms formed in the annealing process 113 or in the formation of subsequent dielectric layers through the atomic hydrogen penetrable layer (referring to the first atomic hydrogen penetrable layer 108 and the optional second atomic hydrogen penetrable layer 124) and the dielectric structure thereunder, thus providing self-repair to the underlying semiconductor device such as transistors thereunder.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a bonding structure, comprising:
providing a substrate;
forming an insulating layer having at least one metal segment formed thereon over the substrate;
forming a first passivation layer over the insulating layer and the metal segment, wherein the first passivation layer comprises a first atomic hydrogen penetrable layer;
forming an opening in the first passivation layer to expose a portion of the metal segment; and
forming a metal layer in the opening to cover the metal segment and a portion of the adjacent passivation layer thereof as a bonding pad.

2. The method as claimed in claim 1, further comprising:
forming a second passivation layer over the first passivation layer and the bonding pad; and
patterning the second passivation layer in a position relative to the bonding pad to partially expose the bonding pad.

3. The method as claimed in claim 2, wherein a second atomic hydrogen penetrable layer is formed over the first passivaiton layer adjacent to the bonding pad prior to formation of the second passivation layer.

4. The method as claimed in claim 1, wherein the first atomic hydrogen penetrable layer is a bottom layer over the insulating layer comprising silicon carbide (SiC) or doped silicon carbide.

5. The method as claimed in claim 2, wherein a second atomic hydrogen penetrable layer comprises silicon carbide (SiC) or doped silicon carbide.

6. The method as claimed in claim 1, wherein the metal segment comprises tungsten, aluminum, copper or an alloy thereof.

7. The method as claimed in claim 1, wherein the metal layer comprises aluminum alloy or aluminum.

8. The method as claimed in claim 1, wherein the first passivation layer comprises silicon oxide or silicon oxyoxide.

9. The method as claimed in claim 2, wherein the second passivation layer is a composite layer comprising a silicon nitride top layer and a bottom layer of silicon oxide or silicon oxynitride.

10. The method as claimed in claim 1, further comprising performing a thermal annealing on the substrate prior to the formation of the metal layer, wherein the thermal annealing uses hydrogen-containing reacting gases.

11. The method as claimed in claim 1, wherein the metal segment is an interconnection via or a conductive line.

12. A bonding structure, comprising:
an insulating layer having at least one metal segment formed thereon; and
a bonding pad over the metal segment, wherein the bonding pad is substantially surrounded by a first passivation layer comprising a first atomic hydrogen penetrable layer.

13. The bonding structure as claimed in claim 12, wherein the atomic hydrogen penetrable layer comprises silicon carbide (SiC) or doped silicon carbide.

14. The bonding structure as claimed in claim 12, further comprising a second passivation layer over the first passiviation layer to partially cover a portion of the bonding pad.

15. The bonding structure as claimed in claim 14, further comprising a second atomic hydrogen penetrable layer disposed between the second passivation layer and the first passivation layer.

16. The bonding structure as claimed in claim 15, wherein the second atomic hydrogen penetrable layer comprises silicon carbide (SiC) or doped silicon carbide.

17. The bonding structure as claimed in claim 12, wherein the metal segment comprises tungsten, aluminum, copper or an alloy thereof.

18. The bonding structure as claimed in claim 12, wherein the bonding pad comprises aluminum alloy or aluminum.

19. The bonding structure as claimed in claim 12, wherein the first passivation layer comprises a silicon oxide or a silicon oxyoxide layer overlying the first atomic hydrogen penetrable layer.

20. The bonding structure as claimed in claim 14, wherein the second passivation layer is a composite layer comprising a silicon nitride top layer and a bottom layer of silicon oxide or silicon oxynitride.

21. The bonding structure as claimed in claim 12, further comprising a conformal diffusion barrier disposed between the bonding pad and the metal segment.

22. The bonding structure as claimed in claim 12, wherein the metal segment is an interconnection via or a conductive line.

23. A bonding structure, comprising:
an insulating layer having at least one metal segment formed thereon;
a bonding pad over the metal segment, wherein the bonding pad is surrounded by a first passivation layer comprising a first atomic hydrogen penetrable layer and a first dielectric top layer; and
a second passivation layer over the first dielectric top layer to partially cover a portion of the bonding pad.

24. The bonding structure as claimed in claim 23, wherein the first atomic hydrogen penetrable layer comprises silicon carbide (SiC) or doped silicon carbide.

25. The bonding structure as claimed in claim 23, further comprising a second atomic hydrogen penetrable layer disposed between the second passivation layer and the first passivation layer.

26. The bonding structure as claimed in claim 25, wherein the second atomic hydrogen penetrable layer comprises silicon carbide (SiC) or doped silicon carbide.
